(19) United States
(12) Patent Application Publication
(10) Pub. No.: US 2026/0190773 A1
(43) Pub. Date: Jul. 2, 2026

(54) Display Apparatus

(71) Applicant: LG Display Co., Ltd., Seoul (KR)

(72) Inventors: Youngtaek Hong, Gangneung-si (KR); Jinseul Ahn, Goyang-si (KR)

(21) Appl. No.: 19/202,678

(22) Filed: May 8, 2025

(30) Foreign Application Priority Data
Dec. 30, 2024 (KR) 10-2024-0201367

(51) Int. Cl. H10K 59/80; H10K 59/131

(52) U.S. Cl. CPC H10K 59/873; H10K 59/131

(57) ABSTRACT

According to an aspect of the present disclosure, a display apparatus includes a substrate including an active area in which a plurality of sub pixels is disposed and a non-active area which encloses the active area, a plurality of light emitting diodes which is disposed in each of the plurality of sub pixels on the substrate and includes an anode, an emission layer, and a cathode, a power line which is disposed on a layer lower than the anode in the non-active area and includes a plurality of protrusion portions protruding from a side surface to the outside, and a plurality of cover layers which is disposed so as to cover ends of the plurality of protrusion portions.

### CROSS-REFERENCE TO RELATED APPLICATION

This application claims the priority of Republic of Korea Patent Application No. 10-2024-0201367 filed on Dec. 30, 2024, which is hereby incorporated by reference in its entirety.

### BACKGROUND

### Field

The present disclosure relates to a display apparatus, and more particularly, to a display apparatus which is capable of minimizing or at least reducing moisture permeation in a non-active area.

### Description of the Related Art

As it enters the information era, a field of a display apparatus which visually expresses electrical information signals has been rapidly developed and studies are continued to improve performances of various display apparatuses, such as a thin-thickness, a light weight, and low power consumption.

A representative display apparatus may include a liquid crystal display apparatus (LCD), a field emission display apparatus (FED), an electro-wetting display apparatus (EWD), and an organic light emitting display apparatus (OLED).

An electroluminescent display apparatus which is represented by an organic light emitting display apparatus is a self-emitting display apparatus so that a separate light source is not necessary, which is different from a liquid crystal display apparatus. Therefore, the electroluminescent display apparatus may be manufactured to have a light weight and a small thickness. Further, since the electroluminescent display apparatus is advantageous not only in terms of power consumption due to the low voltage driving, but also in terms of color implementation, a response speed, a viewing angle, and a contrast ratio (CR), it is expected to be utilized in various fields.

### SUMMARY

An object to be achieved by the present disclosure is to provide a display apparatus which minimizes or at least reduces moisture permeation occurring along a side surface of a power line in a non-active area.

Another object to be achieved by the present disclosure is to provide a low power display apparatus in which a lifespan is improved by improving the reliability of the display apparatus by minimizing or at least reducing the moisture permeation to reduce power consumption.

Objects of the present disclosure are not limited to the above-mentioned objects, and other objects, which are not mentioned above, can be clearly understood by those skilled in the art from the following descriptions.

According to an embodiment of the present disclosure, a display apparatus includes a substrate including an active area in which a plurality of sub pixels is disposed and a non-active area which encloses the active area, a plurality of light emitting diodes which is disposed in each of the plurality of sub pixels on the substrate and includes an anode, an emission layer, and a cathode, a power line which is disposed on a layer lower than the anode in the non-active area and includes a plurality of protrusion portions protruding from a side surface to the outside, and a plurality of cover layers which is disposed so as to cover ends of the plurality of protrusion portions.

According to another embodiment of the present disclosure, a display apparatus includes a substrate including an active area in which a plurality of sub pixels is disposed and a non-active area which encloses the active area, a plurality of light emitting diodes which is disposed in each of the plurality of sub pixels on the substrate and includes an anode, an emission layer, and a cathode, a power line which is disposed on a layer lower than the anode in the non-active area and includes a plurality of protrusion portions protruding from a side surface to the outside, and a plurality of cover layers which is disposed so as to cover ends of the plurality of protrusion portions. Each of the plurality of protrusion portions includes a first part which extends from a side surface of the power line and a second part which extends from the first part to the outside and has a width larger than the first part and each of the plurality of cover layers is disposed on an end of the second part.

Other detailed matters of the exemplary embodiments are included in the detailed description and the drawings.

According to the present disclosure, in the display apparatus, moisture permeation through a power line in the non-active area is minimized or at least reduced to improve the reliability and a display quality of the display apparatus.

According to the present disclosure, in the display apparatus, the moisture permeation through a non-active area is minimized or at least reduced to improve the reliability and the lifespan of the display apparatus, thereby implementing a low-power display apparatus with reduced power consumption.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view of a display apparatus according to an exemplary embodiment of the present disclosure;

FIG. 2 is a cross-sectional view taken along A-A′ of FIG. 1 according to an exemplary embodiment of the present disclosure;

FIG. 3A is an enlarged plan view of an area B of FIG. 1 according to an exemplary embodiment of the present disclosure;

FIG. 3B is an enlarged plan view of an area D of FIG. 3A according to an exemplary embodiment of the present disclosure;

FIG. 4 is a cross-sectional view taken along C-C′ of FIG. 3A according to an exemplary embodiment of the present disclosure;

FIG. 5A is a cross-sectional view taken along E-E′ of FIG. 3B according to an exemplary embodiment of the present disclosure;

FIG. 5B is a cross-sectional view taken along F-F′ of FIG. 3B according to an exemplary embodiment of the present disclosure;

FIG. 5C is an enlarged cross-sectional view of an area G of FIG. 5A according to an exemplary embodiment of the present disclosure;

FIG. 5D is a cross-sectional view taken along H-H′ of FIG. 3A according to an exemplary embodiment of the present disclosure;

FIGS. 6A and 6B are cross-sectional views of a protrusion portion and a cover unit of a display apparatus according to another exemplary embodiment of the present disclosure;

FIGS. 7A and 7B are cross-sectional views of a protrusion portion and a cover unit of a display apparatus according to another exemplary embodiment of the present disclosure;

FIGS. 8A and 8B are cross-sectional views of a protrusion portion and a cover unit of a display apparatus according to another exemplary embodiment of the present disclosure; and

FIG. 9 is an enlarged plan view of a display apparatus according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘comprising’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

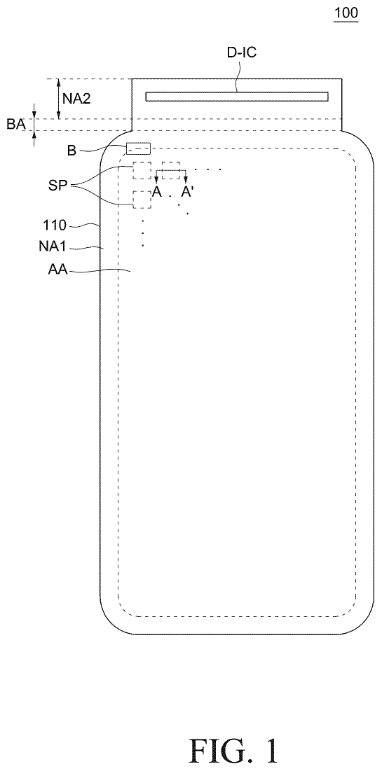

FIG. 1 is a plan view of a display apparatus according to an exemplary embodiment of the present disclosure. In FIG. 1, for the convenience of illustration, among various components of the display apparatus 100, only a substrate 110 is illustrated.

The display apparatus 100 is a device for displaying images to a user. In the display apparatus 100, a display element which displays images, a driving element which drives the display element, and wiring lines which transmit various signals to the display element and the driving element are disposed.

The display element may be defined in different manners depending on the type of the display panel 100. For example, when the display apparatus 100 is an organic light emitting display apparatus, the display element may be an organic light emitting diode which includes an anode, an organic emission layer, and a cathode. For example, when the display apparatus 100 is a liquid crystal display apparatus, the display element may be a liquid crystal display element. Hereinafter, it is assumed that the display apparatus 100 is an organic light emitting display apparatus, but the display apparatus 100 is not limited to the organic light emitting display apparatus.

The substrate 110 is a component for supporting various components included in the display apparatus 100 and may be formed of an insulating material. In the meantime, the substrate 110 is disposed so as to support components on the lowermost portion of the display apparatus 100 so that the substrate is also referred to as a lower substrate, but is not limited thereto.

The substrate 110 includes an active area AA and a non-active area.

The active area AA is an area in which images are displayed in the substrate 110. In the active area AA, a plurality of sub pixels SP which configure a plurality of pixels and a driving circuit for driving the plurality of sub pixels SP may be disposed.

The plurality of sub pixels SP is minimum units which configure the active area AA and a display element may be disposed in each of the plurality of sub pixels SP. For example, an organic light emitting diode which includes an anode, an organic emission layer, and a cathode may be disposed in each of the plurality of sub pixels SP, but it is not limited thereto. Further, the driving circuit for driving the plurality of sub pixels SP may include a driving element and a wiring line. For example, the driving circuit may be configured by a thin film transistor, a storage capacitor, a gate line, and a data line, but is not limited thereto.

The non-active area is an area in which no image is displayed. The non-active area refers to an outer peripheral portion of the substrate 110 which encloses the active area AA. The non-active area may overlap a black matrix. In the non-active area, various wiring lines and circuits for driving an organic light emitting diode in the active area AA are disposed. For example, in the non-active area, a link line which transmits signals to the plurality of sub pixels SP and driving circuits of the active area AA or a driving integrated circuit (IC) (D-IC) such as a gate driver IC or a data driver IC may be disposed, but it is not limited thereto.

The non-active area includes a first non-active area NA1, a bending area BA, and a second non-active area NA2.

The first non-active area NA1 is an area which encloses the active area AA and extends from the active area AA. The bending area BA may extend from one side of the first non-display area NA1 and may be bent. The second non-active area NA2 is an area which extends from the bending area BA to be disposed below the active area.

Referring to FIG. 1, the first non-active area NA1 and the second non-active area NA2 are disposed on the same plane as the active area AA or disposed to be parallel to the active area AA and maintain a flat state. For example, the first non-display area NA1 is disposed to be flat on the same plane as the active area AA and the second non-display area NA2 is disposed below the active area AA to be parallel to the active area AA and be flat. Therefore, the active area AA, the first non-active area NA1, and the second non-active area NA2 may be referred to as non-bending areas, but are not limited thereto.

Referring to FIG. 1, in the second non-active area NA2, the driving IC D-IC is disposed. The driving IC D-IC supplies a data signal to the plurality of sub pixels SP. For example, the driving IC D-IC samples and latches the data signal supplied from the timing controller in response to a data timing control signal supplied from the timing controller to convert the data signal into a gamma reference voltage and output the converted gamma reference voltage. The driving IC D-IC outputs a data signal through the plurality of data lines. For example, in the second non-active area NA2 in which the driving IC D-IC is disposed, a pad unit is disposed and a printed circuit board which is electrically connected to the pad unit is further disposed to supply a signal to the driving IC D-IC, but is not limited thereto.

In the meantime, the driving IC D-IC is disposed on one side of the display panel PN in a chip on panel (COP) manner to be connected to the display panel PN or is disposed in a separate flexible film to be connected to the substrate 110 in a chip on film (COF) manner. In the display apparatus 100 according to the exemplary embodiment of the present disclosure, it is assumed that the driving IC D-IC is disposed in the COP manner, but it is not limited thereto.

At this time, as the substrate 110 is bent, the driving IC D-IC disposed in the second non-active area NA2 is disposed below the active area AA. For example, the driving IC D-IC and the printed circuit board connected to the pad unit of the substrate 110 move to the rear surface of the substrate 110 and overlap the active area AA. Therefore, as seen from the top of the substrate 110, circuit elements, such as the driving IC D-IC and the printed circuit board may not be visible. Accordingly, a size of the non-active area which is visible from the top of the substrate 110 is reduced to implement a narrow bezel.

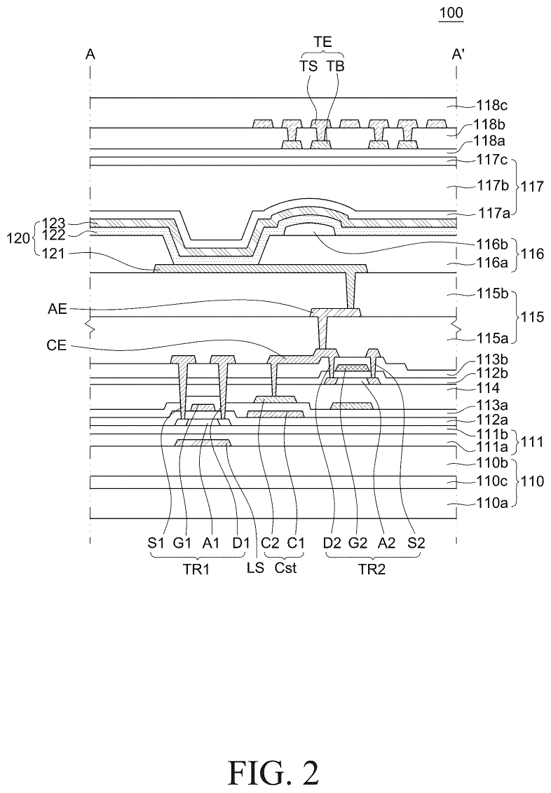

Hereinafter, a cross-sectional structure of the active area AA will be described with reference to FIG. 2 together.

FIG. 2 is a cross-sectional view taken along A-A′ of FIG. 1 according to an exemplary embodiment of the present disclosure. FIG. 2 is a cross-sectional view of one sub pixel SP disposed in an active area AA according to an exemplary embodiment of the present disclosure.

Referring to FIG. 2, in the display apparatus 100 according to the exemplary embodiment of the present disclosure, in the active area AA, a substrate 110, a light shielding layer LS, a first buffer layer 111, a first thin film transistor TR1, a second thin film transistor TR2, a first gate insulating layer 112a, a first interlayer insulating layer 113a, a second buffer layer 114, a second gate insulating layer 112b, a second interlayer insulating layer 113b, a connection electrode CE, a first planarization layer 115a, a second planarization layer 115b, an auxiliary electrode AE, a bank 116a, a spacer 116b, a light emitting diode 120, an encapsulation unit 117, a touch buffer layer 118a, a touch sensing unit, a touch interlayer insulating layer 118b, and a third planarization layer 118c are disposed.

The substrate 110 serves to support and protect components of the display apparatus disposed thereabove.

The substrate 110 is a component for supporting various components included in the display apparatus 100 and may be formed of an insulating material. In the meantime, the substrate 110 is disposed so as to support components on the lowermost portion of the display apparatus 100 so that the substrate is also referred to as a lower substrate, but is not limited thereto.

The substrate 110 includes a first substrate 110a, a second substrate 110b, and an interlayer insulating film 110c. The interlayer insulating film 110c may be disposed between the first substrate 110a and the second substrate 110b. As described above, the substrate 110 is configured by the first substrate 110a, the second substrate 110b, and the interlayer insulating film 110c to suppress the moisture permeation. However, the substrate 110 may be disposed as a single layer, but is not limited thereto.

For example, the first substrate 110a and the second substrate 110b may be polyimide (PI) substrates and the interlayer insulating film 110c may be formed of a single layer of silicon nitride (SiNx) or silicon oxide (SiOx) or multiple layers thereof.

The interlayer insulating film 110c may not be disposed in at least a partial area. For example, the interlayer insulating film 110c may not be formed in an area to which a stress is concentrated, such as a bending area BA or an outermost area.

The light shielding layer LS is disposed on the substrate 110. The light shielding layer LS is a protection layer formed of metal which is disposed below semiconductor layers A1 and A2 of a plurality of transistors TR1 and RT2 to shield external light. The light shielding layer LS minimizes or at least reduces damage of the semiconductor layers A1 and A2 which is caused by the external light.

The first buffer layer 111 is disposed on the substrate 110 while covering the light shielding layer LS. Specifically, a multi-buffer layer 111a is disposed on the substrate 110 while covering the light shielding layer LS and an active buffer layer 110b is disposed on the multi-buffer layer 111a.

The multi-buffer layer 111a delays diffusion of the moisture or oxygen permeating the substrate 110 and includes at least any one of silicon nitride (SiNx) and silicon oxide (SiOx).

The active buffer layer 111b protects the first semiconductor layer A1 and blocks various types of defects introduced from the substrate 110. For example, the active buffer layer 111b includes at least any one of amorous silicon (a-Si), silicon nitride (SiNx), and silicon oxide (SiOx).

The first thin film transistor TR1 may be disposed on the first buffer layer 111. The first thin film transistor TR1 may include the first semiconductor layer A1, a first gate electrode G1, a first source electrode S1, and a first drain electrode D1. Here, depending on the design of the pixel circuit, the first source electrode S1 may serve as a first drain electrode and the first drain electrode D1 may serve as a first source electrode.

The first semiconductor layer A1 is disposed on the first buffer layer 111 and overlaps the light shielding layer LS. The first semiconductor layer A1 may include amorphous silicon or polycrystalline silicon. For example, the first semiconductor layer A1 may include a low-temperature polycrystalline silicon LTPS. For example, the polycrystalline silicon material has a high mobility (100 cm2/Vs or higher) so that energy power consumption is low and reliability is excellent. Therefore, the polysilicon material may be applied to a gate driver for driving elements which drive thin film transistors for a display element and/or a multiplexer (MUX) and also applied as a first semiconductor layer A1 of a driving thin film transistor of the display apparatus 100 according to the exemplary embodiment of the present disclosure, but is not limited thereto. For example, the polycrystalline silicon material may also be applied as a second semiconductor layer A2 of the switching thin film transistor according to the characteristic of the display apparatus 100. An amorphous silicon (a-Si) material is deposited on the first buffer layer 111 and a dehydrogenation process and a crystallization process are performed to form polycrystalline silicon and the polycrystalline silicon is patterned to form the first semiconductor layer A1.

Here, the first semiconductor layer A1 includes a first channel region in which a channel is formed when the first thin film transistor T1 is driven and a first source region and a first drain region on both sides of the first channel region. The first source region refers to a part of the first semiconductor layer A1 which is connected to the first source electrode S1 and the first drain region refers to a part of the first semiconductor layer A1 which is connected to the first drain electrode D1. For example, the first source region and the first drain region are configured by ion-doping (impurity doping) of the first semiconductor layer A1. The first source region and the first drain region may be generated by doping ions into the polycrystalline silicon material and the first channel region may refer to a part in which the ions are not doped, but the polycrystalline silicon material remains.

The first gate insulating layer 112a is disposed on the first semiconductor layer A1. The first gate insulating layer 112a may be configured by a single layer of silicon nitride (SiNx) or silicon oxide (SiOx) or a multilayer thereof. In the first gate insulating layer 112a, a contact hole through which the first source electrode S1 and the first drain electrode D1 of the first thin film transistor TR1 are connected to the first source region and the first drain region of the first semiconductor layer A1 of the first thin film transistor TR1, respectively, may be formed.

The first gate electrode G1 of the first thin film transistor TR1 and a first capacitor electrode C1 of the storage capacitor Cst may be disposed on the first gate insulating layer 112a.

At this time, the first gate electrode G1 and the first capacitor electrode C1 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 may be formed on the first gate insulating layer 112a and overlaps the first channel region of the first semiconductor layer A1 of the first thin film transistor TR1.

The first capacitor electrode C1 may be omitted based on a driving characteristic of the display apparatus 100 and a structure and a type of the thin film transistor. The first gate electrode G1 and the first capacitor electrode C1 may be formed by the same process. Further, the first gate electrode G1 and the first capacitor electrode C1 may be formed of the same material on the same layer.

The first interlayer insulating layer 113a may be disposed above the first gate insulating layer 112a, the first gate electrode G1, and the first capacitor electrode C1. The first interlayer insulating layer 113a may be configured by a single layer of silicon nitride SiNx or silicon oxide SiOx or a multilayer thereof. In the first interlayer insulating layer 113a, a contact hole for exposing the first source region and the first drain region of the first semiconductor layer A1 of the first thin film transistor TR1 may be formed.

A second capacitor electrode C2 of the storage capacitor Cst may be disposed on the first interlayer insulating layer 113a. The second capacitor electrode C2 may be formed by a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 may be formed on the first interlayer insulating layer 113a and overlaps the first capacitor electrode C1. Further, the second capacitor electrode C2 may be formed of the same material as the first capacitor electrode C1. The second capacitor electrode C2 may be omitted based on a driving characteristic of the display apparatus 100 and a structure and a type of the thin film transistor.

The second buffer layer 114 may be disposed on the first interlayer insulating layer 113a and the second capacitor electrode C2. The second buffer layer 114 may be configured by a single layer of silicon nitride SiNx or silicon oxide SiOx or a multi-layer thereof. A contact hole for exposing the first source region and the first drain region of the first semiconductor layer A1 of the first thin film transistor TR1 may be formed in the second buffer layer 114. Further, in the second buffer layer 114, a contact hole for exposing the second capacitor electrode C2 of the storage capacitor Cst may be formed.

The second buffer layer 114 may be formed by a multiple layer, but is not limited thereto.

The second semiconductor layer A2 of the second thin film transistor TR2 may be disposed on the second buffer layer 114. Here, the second thin film transistor TR2 may include the second semiconductor layer A2, a second gate insulating layer 112b, a second gate electrode G2, a second source electrode S2, and a second drain electrode D2. Here, depending on the design of the pixel circuit, the second source electrode S2 may serve as a drain electrode and the second drain electrode D2 may serve as a source electrode.

Further, the second semiconductor layer A2 includes a second channel region in which a channel is formed when the second thin film transistor TR2 is driven and a second source region and a second drain region on both sides of the second channel region. The second source region refers to a part of the second semiconductor layer A2 which is connected to the second source electrode S2 and the second drain region refers to a part of the second semiconductor layer A2 which is connected to the second drain electrode D2.

The second semiconductor layer A2 may be formed of an oxide semiconductor. The oxide semiconductor material has a larger band gap than a silicon material so that electrons cannot jump over the band gap in an off state. Therefore, the oxide semiconductor material has a low off-current. Therefore, the thin film transistor including a semiconductor layer which is formed of an oxide semiconductor is suitable for a switching thin film transistor which maintains on-time to be short and off-time to be long, but is not limited thereto.

Depending on the characteristic of the display apparatus 100, a thin film transistor including a semiconductor layer formed of oxide semiconductor may be applied as a driving thin film transistor. Further, due to the small off-current, a magnitude of an auxiliary capacitance may be reduced so that the oxide semiconductor may be appropriate for a high resolution display element. For example, the second semiconductor layer A2 may be formed of metal oxide and for example, may be formed of various metal oxide such as indium-gallium-zinc-oxide (IGZO). Here, the description was made under assumption that the second semiconductor layer A2 of the second thin film transistor TR2 is configured by IGZO, among various metal oxides, but it is not limited thereto. Therefore, the active layer may be formed of another metal oxide such as indium-zinc-oxide (IZO), indium-gallium-tin-oxide (IGTO), or indium-gallium-oxide (IGO), rather than IGZO.

The second semiconductor layer A2 may be formed by depositing the metal oxide on the second buffer layer 114, performing a heat treatment for stabilization, and then patterning the metal oxide.

The second gate insulating layer 112b may be disposed on the entire substrate 110 including the second semiconductor layer A2. For example, the second gate insulating layer 112b may be configured by a single layer of silicon nitride SiNx or silicon oxide SiOx or a multilayer thereof.

The second gate electrode G2 may be disposed on the second gate insulating layer 112b.

The second gate electrode G2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material may be used.

The second interlayer insulating layer 113b is disposed on the second gate insulating layer 112b and the second gate electrode G2. A contact hole for exposing the first semiconductor layer A1 of the first thin film transistor TR1 and the second semiconductor layer A2 of the second thin film transistor TR2 may be formed in the second interlayer insulating layer 113b. For example, a contact hole for exposing the first source region and the first drain region of the first semiconductor layer A1 of the first thin film transistor TR1 may be formed in the second interlayer insulating layer 113b. A contact hole for exposing the second source region and the second drain region of the second semiconductor layer A2 of the second thin film transistor TR2 may be formed in the second interlayer insulating layer 113b.

The second interlayer insulating layer 113b may be configured as a single layer of silicon nitride SiNx or silicon oxide SiOx or a multi-layer thereof.

The connection electrode CE, the first source electrode S1 and the first drain electrode D1 of the first thin film transistor TR1 and the second source electrode S2 and the second drain electrode D2 of the second thin film transistor TR2 may be disposed on the second interlayer insulating layer 113b.

The connection electrode CE may be electrically connected to the second drain electrode D2 of the second thin film transistor TR2. Further, the connection electrode CE may be electrically connected to the second capacitor electrode C2 of the storage capacitor Cst through the contact holes formed in the second buffer layer 114 and the second interlayer insulating layer 113b. That is, the connection electrode CE may serve to electrically connect the second capacitor electrode C2 of the storage capacitor Cst and the second drain electrode D2 of the second thin film transistor TR2 to each other.

Here, the first source electrode S1 and the first drain electrode D1 of the first thin film transistor TR1 may be connected to the first semiconductor layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 may be connected to the second semiconductor layer A2 through the contact hole formed in the second interlayer insulating layer 112b.

The connection electrode CE, the first source electrode S1 and the first drain electrode D1 of the first thin film transistor TR1 and the second source electrode S2 and the second drain electrode D2 of the second thin film transistor TR2 may be formed of the same material by the same process.

For example, the connection electrode CE, the first source electrode S1 and the first drain electrode D1 of the first thin film transistor TR1 and the second source electrode S2 and the second drain electrode D2 of the second thin film transistor TR2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. For example, the connection electrode CE, the first source electrode S1 and the first drain electrode D1 of the first thin film transistor TR1 and the second source electrode S2 and the second drain electrode D2 of the second thin film transistor TR2 may be formed of a triple layered structure of titanium (Ti)/aluminum (Al)/titanium (Ti), but are not limited thereto.

The connection electrode CE may be integrally formed to be connected to the second drain electrode D2 of the second thin film transistor TR2, but is not limited thereto.

The first planarization layer 115a may be disposed on the connection electrode CE, the first source electrode S1 and the first drain electrode D1 of the first thin film transistor TR1, the second source electrode S2 and the second drain electrode D2 of the second thin film transistor TR2, and the second interlayer insulating layer 113b.

The first planarization layer 115a may be an organic layer which planarizes and protects upper portions of the first thin film transistor TR1 and the second thin film transistor TR2. For example, the first planarization layer 115a may be formed of an organic material such as acryl resin, epoxy resin, phenolic resin, polyamide resin, or polyimide resin.

The auxiliary electrode AE may be disposed on the first planarization layer 115a. The auxiliary electrode AE may be connected to the second drain electrode D2 of the second thin film transistor TR2 through the contact hole of the first planarization layer 115a. The auxiliary electrode AE may serve to electrically connect the second thin film transistor TR2 and the first electrode 121 with each other. The auxiliary electrode AE may be formed in a triple layered structure of titanium (Ti)/aluminum (Al)/titanium (Ti). The auxiliary electrode AE may be formed of the same material as the second source electrode S2 and the second drain electrode D2 of the second thin film transistor TR2.

The second planarization layer 115b may be disposed above the auxiliary electrode AE and the first planarization layer 115a. For example, the second planarization layer 115b may be formed of an organic material, such as acryl resin, epoxy resin, phenolic resin, polyamide resin, or polyimide resin.

The light emitting diode 120 is disposed on the second planarization layer 115b. The light emitting diode 120 includes an anode 121, an emission layer 122, and a cathode 123.

The anode 121 is disposed on the second planarization layer 115b. At this time, the anode 121 may be electrically connected to the auxiliary electrode AE through the contact hole provided in the second planarization layer 115b. The anode 121 is formed of a metallic material.

When the display apparatus 100 is a top emission type in which light emitted from the light emitting diode 120 is emitted above the substrate 110 on which the light emitting diode 120 is disposed, the anode 120 may include a reflective layer and a transparent conductive layer disposed on the reflective layer. The transparent conductive layer may be formed of transparent conductive oxide such as indium tin oxide (ITO) or indium zinc oxide (IZO) and the reflective layer is formed of silver (Ag), aluminum (Al), gold (Au), molybdenum (Mo), tungsten (W), chrome (Cr), or an alloy thereof, but they are not limited thereto.

The bank unit 116 is disposed on the anode 121. The bank unit 116 includes a bank 116a and a spacer 116b.

The bank 116a may be disposed while covering an end of the anode 121. A part of the bank 116a corresponding to an emission area of the sub pixel may be open. A part of the anode 121 may be exposed through the open part of the bank 116a (hereinafter, referred to as an open area). At this time, the bank 116a may be formed of an inorganic insulating material, such as silicon nitride (SiNx) or silicon oxide (SiOx), or an organic insulating material, such as benzocyclobutene resin, acrylic resin or imide resin, but is not limited thereto.

The spacer 116b may be further disposed on the bank 116a. The spacer 116b may serve to maintain a predetermined gap so as not to allow a mask to be in contact with a substrate during a manufacturing process of an emission layer 122 of the light emitting diode 120 which is formed of an organic material.

For example, the spacer 116b may be formed of an inorganic insulating material, such as silicon nitride (SiNx) or silicon oxide (SiOx), or an organic insulating material, such as benzocyclobutene resin, acrylic resin or imide resin, but is not limited thereto.

The emission layer 122 is disposed on the anode 121, the bank 116a, and the spacer 116b. The emission layer 122 may be disposed in the open area of the bank 116a and in the vicinity of the open area of the bank. Therefore, the emission layer 122 may be disposed on the anode 121 exposed through the open area of the bank 116.

The emission layer 122 may include a plurality of organic material layers. For example, the emission layer 122 may include an organic material layer such as a hole injection layer, a hole transport layer, an electron transport layer, and an electron injection layer. In the meantime, when the emission layer 122 emits white light, light emitted from the emission layer 122 may be converted into light with various colors by a plurality of color filters CF, but is not limited thereto.

The cathode 123 is disposed on the emission layer 122. The cathode 123 supplies electrons to the emission layer 122 so that the cathode may be formed of a conductive material having a low work function. The cathode 123 may be formed as one layer over the plurality of sub pixels SP. That is, the cathodes 123 of the plurality of sub pixels SP are connected to be integrally formed.

For example, the cathode 123 may be formed of a transparent conductive material such as indium tin oxide (ITO) and indium zinc oxide (IZO) or ytterbium (Yb) alloy and may further include a metal doping layer, but is not limited thereto.

The encapsulation unit 117 is disposed on the light emitting diode 120.

The encapsulation unit 117 may have a single layer structure or a multi-layered structure. For example, the encapsulation unit 117 may have a multi-layered structure including a first encapsulation layer 117a, a second encapsulation layer 117b, and a third encapsulation layer 117c. However, the encapsulation unit may also be formed with a single layer structure, but is not limited thereto.

The first encapsulation layer 117a and the third encapsulation layer 117c are formed of inorganic materials and the second encapsulation layer 117b is formed of an organic material. The second encapsulation layer 117b may be the thickest among the first encapsulation layer 117a, the second encapsulation layer 117b, and the third encapsulation layer 117c. The second encapsulation layer 117b may planarize an upper portion of the light emitting diode 120.

The first encapsulation layer 117a is disposed on the cathode 123 and is disposed to be most adjacent to the light emitting diode 120, in the encapsulation unit 117. For example, the first encapsulation layer 117a is configured by silicon nitride SiNx, silicon oxide (SiOx), silicon oxynitride (SiON), or aluminum oxide (Al2O3), but is not limited thereto.

The second encapsulation layer 117b may be formed to have a smaller area than that of the first encapsulation layer 117a. In this case, the second encapsulation layer 117b may be formed to expose both ends of the first encapsulation layer 117a. The second encapsulation layer 117b may serve to enhance a buffering function to alleviate stress between the layers due to bending of the flexible display apparatus and a planarization function.

For example, the second encapsulation layer 117b is formed of an organic insulating material, such as acrylic resin, epoxy resin, polyimide, polyethylene, or silicon oxy carbon (SiOC). For example, the second encapsulation layer 117b may be formed by an inkjet method, but is not limited thereto.

The third encapsulation layer 117c may be formed above the substrate 110 on which the second encapsulation layer 117b is formed so as to cover upper surfaces and side surfaces of the second encapsulation layer 117b and the first encapsulation layer 117a. At this time, the third encapsulation layer 117c may minimize or block the permeation of external moisture or oxygen into the first encapsulation layer 117a and the second encapsulation layer 117b. For example, the third encapsulation layer 117c is configured by an inorganic insulating material, such as silicon nitride SiNx, silicon oxide (SiOx), silicon oxynitride (SiON), or aluminum oxide (Al2O3), but may be limited thereto.

The touch sensing unit may be disposed on the encapsulation unit 117.

The touch sensing unit includes the touch buffer layer 118a, the touch interlayer insulating layer 118b, the touch electrode TE, and the third planarization layer 118c. The touch electrode TE may include a touch sensor electrode TS and a touch bridge electrode TB located on different layers.

For example, the touch buffer layer 118a is disposed on the third encapsulation layer 117c and the touch bridge electrode TB is disposed on the touch buffer layer 118a.

The touch interlayer insulating layer 118b is disposed on the touch bridge electrode TB and the touch sensor electrode TS is disposed on the touch interlayer insulating layer 118b.

The third planarization layer 118c is disposed on the touch sensor electrode TS. The third planarization layer 118c may be an organic layer which planarizes and protects an upper portion of the touch sensor electrode TS. Therefore, the third planarization layer 118c is disposed to be in contact with the touch sensor electrode TS. For example, the third planarization layer may be formed of an organic material such as acryl resin, epoxy resin, phenolic resin, polyamide resin, or polyimide resin, but is not limited thereto. The touch buffer layer 118a, the touch interlayer insulating layer 118b, and the third planarization layer 118c may be formed of an inorganic insulating material or an organic insulating material. Therefore, the touch buffer layer 118a, the touch interlayer insulating layer 118b, and the third planarization layer 118c may minimize or at least reduce a step in a location where the touch electrode TE is disposed and electrically insulate the touch sensor electrode TS from the touch bridge electrode TB.

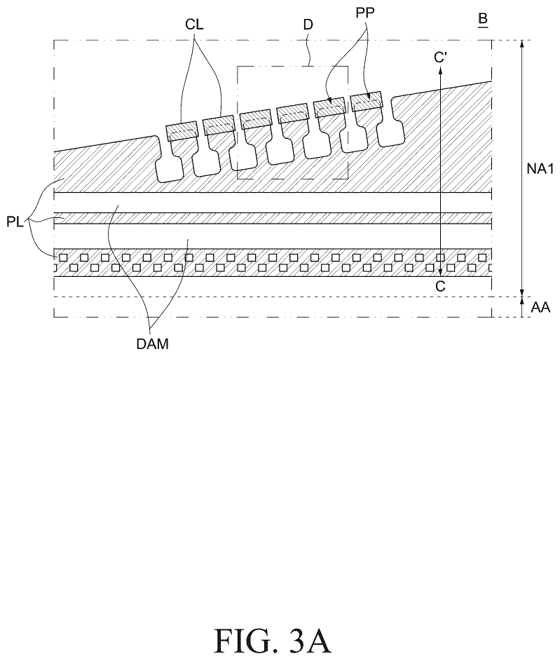

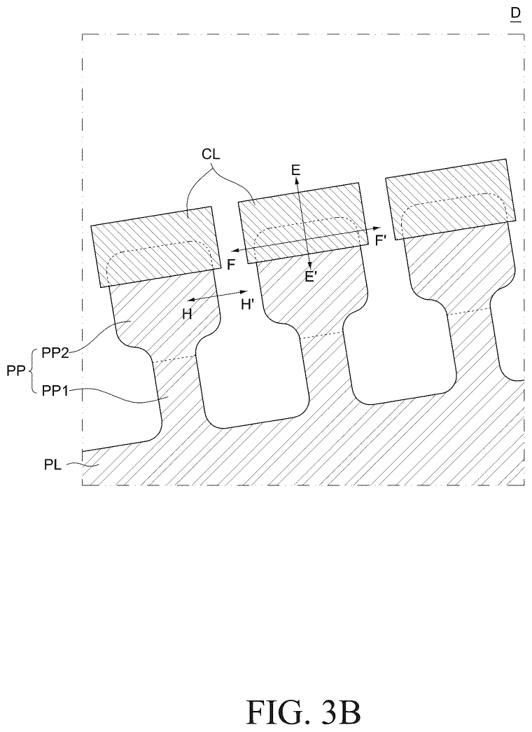

Hereinafter, a cross-sectional structure of the first non-active area NA1 adjacent to the bending area BA will be described with reference to FIGS. 3A to 5D together.

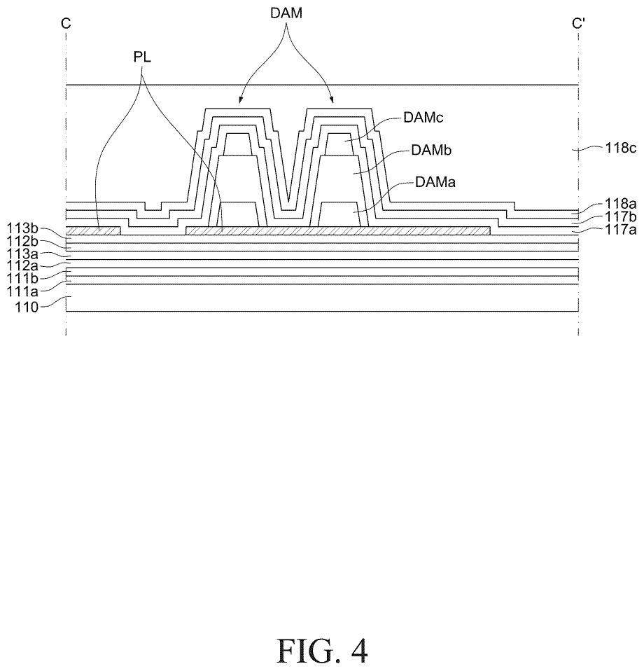

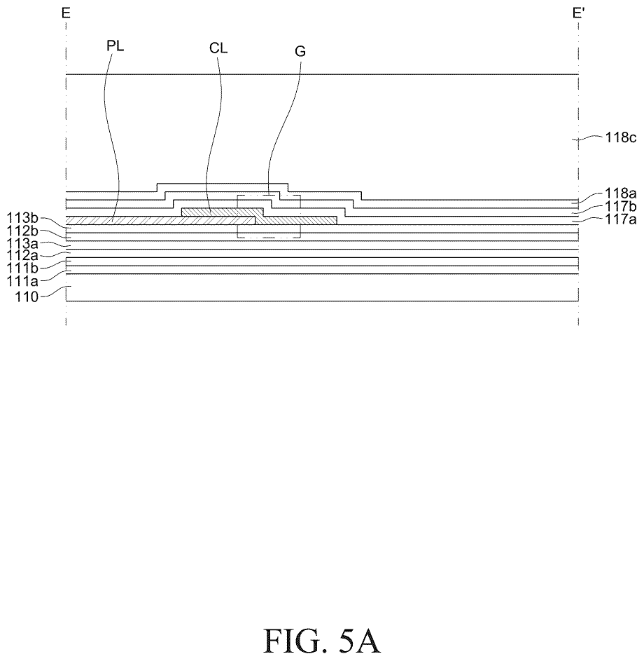

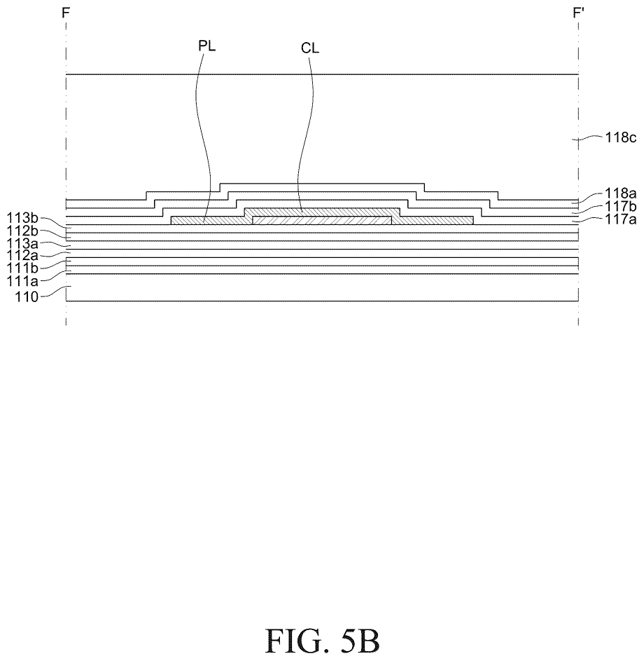

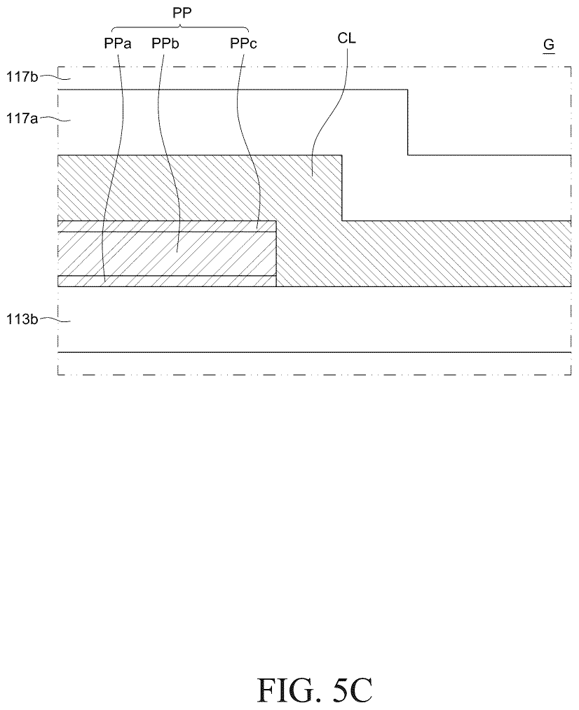

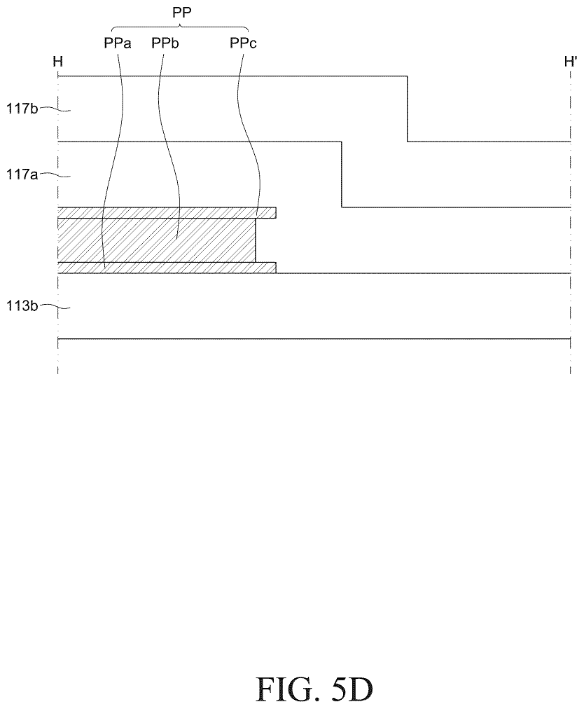

FIG. 3A is an enlarged plan view of an area B of FIG. 1 according to an exemplary embodiment of the present disclosure. FIG. 3B is an enlarged plan view of an area D of FIG. 3A according to an exemplary embodiment of the present disclosure. FIG. 4 is a cross-sectional view taken along C-C′ of FIG. 3A according to an exemplary embodiment of the present disclosure. FIG. 5A is a cross-sectional view taken along E-E′ of FIG. 3B according to an exemplary embodiment of the present disclosure. FIG. 5B is a cross-sectional view taken along F-F′ of FIG. 3B according to an exemplary embodiment of the present disclosure. FIG. 5C is an enlarged cross-sectional view of an area G of FIG. 5A according to an exemplary embodiment of the present disclosure. FIG. 5D is a cross-sectional view taken along H-H′ of FIG. 3A according to an exemplary embodiment of the present disclosure. FIGS. 3A to 5D are cross-sectional views and plan views of each area of the non-active area NA1 according to an exemplary embodiment of the present disclosure. In FIGS. 5C and 5D, for the sake of convenience, among various components of the display apparatus 100, only a protrusion portion PP and a cover layer CL are illustrated.

Referring to FIGS. 3A to 5D, in the display apparatus 100 according to the exemplary embodiment of the present disclosure, in the first non-active area NA1 of the substrate 100, a power line PL, a protrusion portion PP, a cover layer CL, a plurality of dams DAM, and a third planarization layer 118c are disposed.

In the first non-active area NA1, the power line PL is disposed on the second interlayer insulating layer 113b. For example, a low potential voltage or a high potential voltage is supplied to the sub pixel SP of the display apparatus 100 through the power line PL. The power line PL is disposed on a lower layer than the anode 121. For example, the power line PL may be formed on the same layer as the auxiliary electrode AE disposed in the active area AA with the same material, but is not limited thereto.

In the meantime, referring to FIGS. 3A and 4, the power line PL includes a plurality of holes. Therefore, gas which is generated from the first interlayer insulating layer 113a or the first encapsulation layer 117a during the manufacturing process is easily discharged to the outside through the plurality of holes of the power line PL.

Referring to FIGS. 3A to 5D, the power line PL includes a plurality of protrusion portions PP. The plurality of protrusion portions PP may be parts protruding from the side surface of the power line PL to the outside. Therefore, the plurality of protrusion portions PP increases a length of the side surface of the power line PL to minimize the propagation of moisture permeation which may occur through the side surface of the power line PL.

The plurality of protrusion portions PP includes a first part PP1 and a second part PP2.

The first part PP1 extends from the side surface of the power line PL to the outside of the power line PL. For example, the first part PP1 may extend in a straight line, but is not limited thereto.

The second part PP2 extends from the first part PP1 to the outside and has a width larger than that of the first part PP1. Therefore, a shape formed by the first part PP1 and the second part PP2 may be a hammer shape, for example, but is not limited thereto.

In the meantime, referring to FIGS. 5C and 5D, the plurality of protrusion portions PP includes a first layer PPa, a second layer PPb, and a third layer PPc. For example, the first layer PPa and the third layer PPc include titanium (Ti) and the second layer PPb includes aluminum (Al).

Referring to FIGS. 3A, 3B and 5A to 5C, the plurality of cover layers CL are disposed in ends of the plurality of protrusion portions PP. The plurality of cover layers CL are disposed in the ends of the plurality of protrusions PP. For example, the plurality of cover layers CL may be disposed in ends of the second parts PP2 of the plurality of protrusion portions PP. Referring to FIGS. 5A and 5B, the plurality of cover layers CL are disposed so as to cover side surfaces and top surfaces of the ends of the plurality of protrusion portions PP.

For example, the plurality of cover layers CL are formed of the same material as the anode 121 disposed in the active area AA. For example, the plurality of cover layers CL are formed by the same process with the same material as the anode 121 disposed in the active area AA, but is not limited thereto. Therefore, the plurality of cover layers CL are configured to cover the ends of the plurality of protrusion portions PP and protect the ends of the plurality of protrusion portions PP from an etching solution, after a step of forming the anode 121, for example, during the processing process such as dry etching.

At this time, referring to FIG. 5C, side surfaces of the first layer PPa, the second layer PPb, and the third layer PPc which overlap the plurality of cover layers CL at the ends of the plurality of protrusion portions PP are disposed on the same plane. Further, referring to FIG. 5D, on a side surface which does not overlap the plurality of cover layers CL, among the side surfaces of the plurality of protrusion portions PP, a side surface of the second layer PPb is disposed inside more than side surfaces of the first layer PPa and the third layer PPc. A side surface which does not overlap the plurality of cover layers CL, among the side surfaces of the plurality of protrusion portions PP is disposed to be in contact with the first encapsulation layer 171a.

For example, aluminum included in the second layer PPb of the power line PL during the processing process may be more susceptible to erosion than titanium included in the first layer PPa and the third layer PPc. Therefore, aluminum (Al) included in the second layer PPb is eroded so that on a side surface, among the side surfaces of the plurality of protrusion portions PP, which does not overlap the plurality of cover layers CL, an end of the second layer PPb may be disposed inside more than the ends of the first layer PPa and the third layer PPc, as illustrated in FIG. 5D.

In contrast, the side surfaces of the plurality of protrusion portions PP which overlap the plurality of cover layers CL at the ends of the plurality of protrusion portions PP are covered by the plurality of cover layers CL during the processing process so that the erosion of the aluminum (Al) included in the second layer PPb may be minimized. Therefore, as illustrated in FIG. 5C, side surfaces of the first layer PPa, the second layer PPb, and the third layer PPc which overlap the plurality of cover layers CL are disposed on the same plane.

Referring to FIGS. 3A and 4, the plurality of dams DAM are disposed on the power line Pl in the first non-active area NA1. The plurality of dams DAM overlap a part of the power line PL. Each of the plurality of dams DAM is disposed so as to enclose the active area AA in the first non-active area NA1.

The plurality of dams DAM are disposed to be adjacent to the active area AA to suppress excessive application of the organic encapsulation layer 117b.

The plurality of dams DAM have a structure in which a plurality of organic layers formed by the same material as components disposed in the active area AA are laminated. For example, each of the plurality of dams DAM includes a first layer DAMa, a second layer DAMb, and a third dam DAMc. The first layer DAMa is formed by the same process with the same material as the second planarization layer. The second layer DAMb is formed by the same process with the same material as the bank 116a. The third layer DAMc is formed by the same process with the same material as the spacer 116b. However, it is not limited thereto.

Further, even though in FIGS. 3A and 4, it is illustrated that the plurality of dams DAM are configured by two, it is not limited thereto and the number of the plurality of dams may be changed if necessary.

Among the power lines disposed in the non-active area in the display apparatus, in an area in which the power line is exposed from the organic insulating layer, a plurality of protrusion portions may be disposed. The plurality of protrusion portions increase a length of a side surface of the power line to minimize or at least reduce propagation of moisture permeation occurring along the side surface of the power line.

However, if a power line which is formed with a triple structure of titanium (Ti), aluminum (Al), and titanium (Ti), among the power lines, is covered by only an inorganic insulating layer, rather than the organic insulating layer, aluminum (Al) which is exposed from the side surface of the power line may be more susceptible to erosion than titanium during the processing process. Therefore, on the side surface of the power line which is not covered by the organic insulating layer, a void or seam structure in which an aluminum layer of the triple structure is eroded so that an end of the aluminum (Al) layer is disposed inside from ends of the titanium (Ti) layers may be generated. The void or seam structure may act as a capillary along the side surface of the power line so that the moisture may permeate due to the capillary phenomenon. Therefore, there may be a serious problem in that the reliability and the display quality of the display apparatus are degraded due to the moisture permeation through the void or seam structure.

In the display apparatus 100 according to the exemplary embodiment of the present disclosure, a cover layer CL which covers ends of the plurality of protrusion portions PP of the power line PL is disposed to minimize or at least reduce the moisture permeation through the side surfaces of the plurality of protrusion portions PP.

Specifically, in the display apparatus 100 according to the exemplary embodiment of the present disclosure, the plurality of protrusion portions PP are disposed on the side surface of the power line PL. The plurality of cover layers CL are disposed on the ends of the plurality of protrusion portions PP. The plurality of cover layers CL are formed of the same material as the auxiliary electrode AE and cover a side surface and a top surface of the power line PL which may be formed with a triple structure of titanium (Ti)/aluminum (Al)/titanium (Ti). Therefore, the ends of the plurality of protrusion portions PP are protected during the process to minimize or at least reduce erosion of the second layer PPb of the protrusion portion PP including aluminum (Al) of the power line PL and minimize a void or seam structure which occurs on the ends of the plurality of protrusion portions PP. Therefore, the void or seam structure is disconnected in at least a part along the side surfaces of the plurality of protrusion portions PP of the power line PL. Therefore, the moisture permeation due to the capillary phenomenon which may occur through the void or seam structure formed along the side surfaces of the plurality of protrusion portions PP may be minimized or at least reduced. Accordingly, in the display apparatus 100 according to the exemplary embodiment of the present disclosure, a cover layer CL which covers ends of the plurality of protrusion portions PP of the power line PL is disposed. Therefore, the moisture permeation through the side surfaces of the plurality of protrusion portions PP may be minimized or at least reduced and the display quality and the reliability of the display apparatus 100 may be improved.

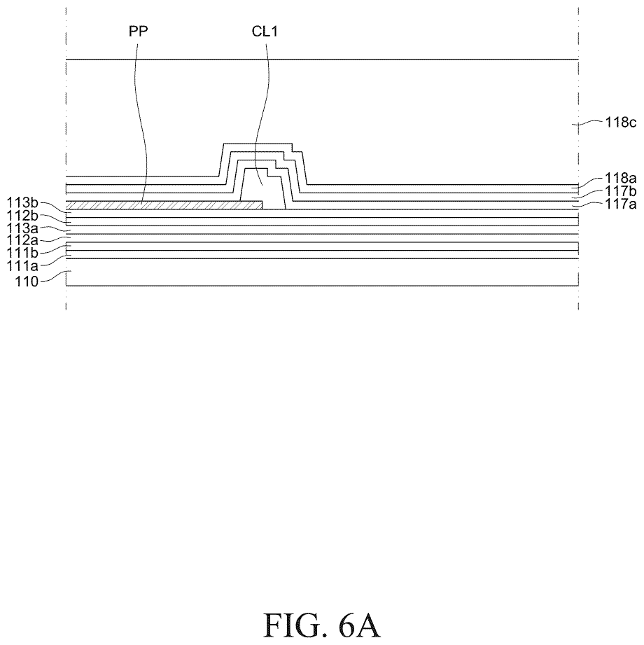

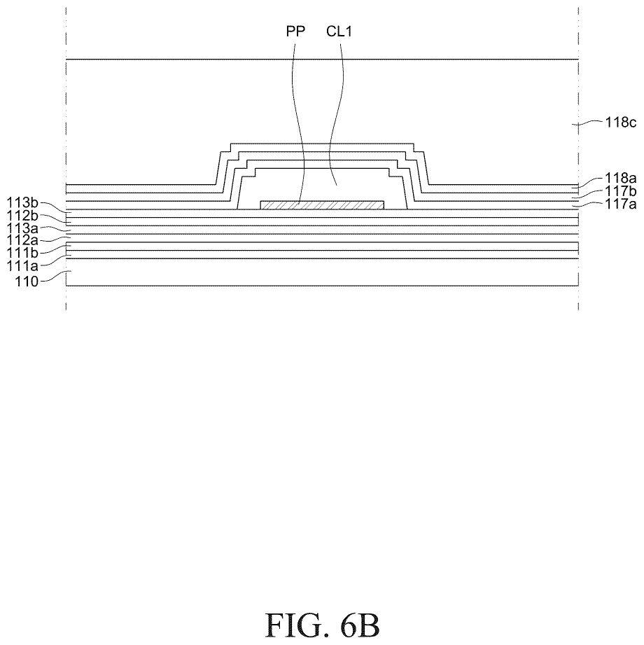

FIGS. 6A and 6B are cross-sectional views of a protrusion portion and a cover unit of a display apparatus according to another exemplary embodiment of the present disclosure. The only difference between a display apparatus 600 of FIGS. 6A and 6B and the display apparatus 100 of FIGS. 1 to 5D is a first cover layer CL1, so that a redundant description for the substantially same part will be omitted. The same configuration will be denoted with the same reference numeral.

The plurality of cover layers CL include a plurality of first cover layers CL1.

Referring to FIGS. 6A and 6B, the plurality of first cover layers CL1 are disposed on ends of the plurality of protrusion portions PP. The plurality of first cover layers CL1 are disposed so as to cover side surfaces and top surfaces of the plurality of protrusion portions PP.

For example, the plurality of first cover layers CL1 are formed of the same material as the second planarization layer 115b disposed in the active area AA. For example, the plurality of first cover layers CL1 are formed by the same process with the same material as the second planarization layer 115b disposed in the active area AA, but is not limited thereto. Therefore, the plurality of cover layers CL are configured to cover and protect ends the plurality of protrusion portions PP in a process after the step of forming the second planarization layer 115b.

In the display apparatus 600 according to another exemplary embodiment of the present disclosure, a first cover layer CL1 which covers ends of the plurality of protrusion portions PP of the power line PL is disposed to minimize or at least reduce the moisture permeation through the side surfaces of the plurality of protrusion portions PP.

Specifically, in the display apparatus 100 according to another exemplary embodiment of the present disclosure, the plurality of protrusion portions PP are disposed on the side surface of the power line PL. The plurality of first cover layers CL1 are disposed on the ends of the plurality of protrusion portions PP. The plurality of first cover layers CL1 are formed of the same material as the second planarization layer 115b and covers a side surface and a top surface of the power line PL which may be formed with a triple structure of titanium (Ti)/aluminum (Al)/titanium (Ti). Therefore, the ends of the plurality of protrusion portions PP are protected during the process to minimize erosion of the second layer PPb of the protrusion portion PP including aluminum (Al) of the power line PL and minimize a void or seam structure which occurs on the ends of the plurality of protrusion portions PP. Therefore, the void or seam structure is disconnected in at least a part along the side surfaces of the plurality of protrusion portions PP of the power line PL so that the moisture permeation due to the capillary phenomenon which may occur through the void or seam structure formed along the side surfaces of the plurality of protrusion portions PP may be minimized. Accordingly, in the display apparatus 600 according to the exemplary embodiment of the present disclosure, the first cover layer CL1 which covers ends of the plurality of protrusion portions PP of the power line PL is disposed. Therefore, the moisture permeation through the side surfaces of the plurality of protrusion portions PP may be minimized or at least reduced and the display quality and the reliability of the display apparatus 600 may be improved.

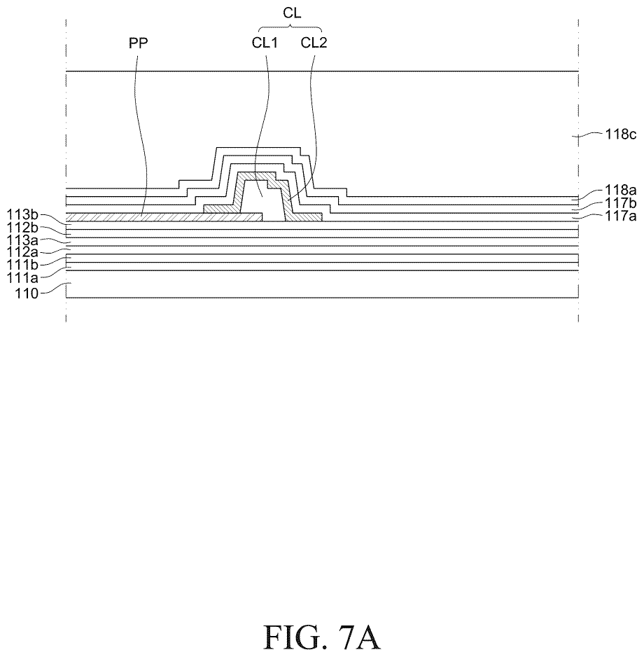

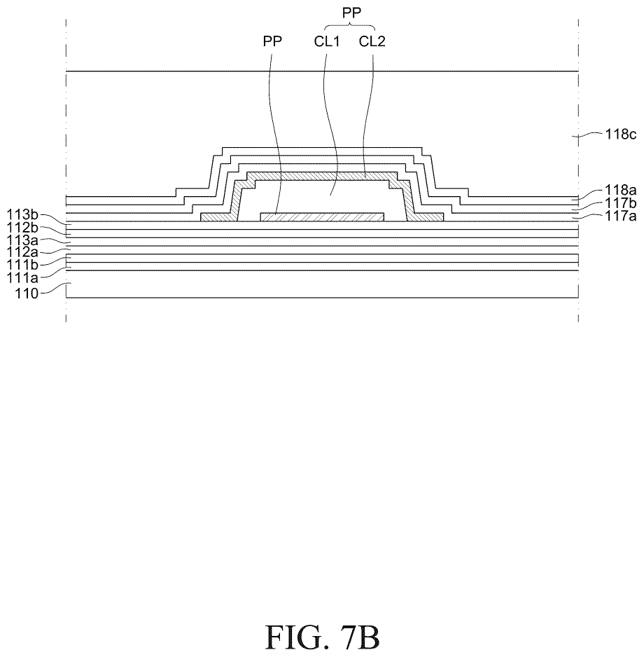

FIGS. 7A and 7B are cross-sectional views of a protrusion portion and a cover unit of a display apparatus according to still another exemplary embodiment of the present disclosure. The only difference between a display apparatus 700 of FIGS. 7A and 7B and the display apparatus 600 of FIGS. 6A to 6B is that a second cover layer CL2 is further disposed, so that a redundant description for the substantially same part will be omitted. The same configuration will be denoted with the same reference numeral.

The plurality of cover layers CL include a plurality of first cover layers CL1 and a plurality of second cover layers CL2.

Referring to FIGS. 7A and 7B, the plurality of first cover layers CL1 are disposed on ends of the plurality of protrusion portions PP. The plurality of first cover layers CL1 are disposed so as to cover side surfaces and top surfaces of the plurality of protrusion portions PP.

For example, the plurality of first cover layers CL1 are formed of the same material as the second planarization layer 115b disposed in the active area AA. For example, the plurality of first cover layers CL1 are formed by the same process with the same material as the second planarization layer 115b disposed in the active area AA, but is not limited thereto.

Referring to FIGS. 7A and 7B, the plurality of second cover layers CL1 are disposed on the plurality of first cover layers CL2. For example, the plurality of second cover layers CL2 may be disposed so as to overlap the end of the second parts PP2 of the plurality of protrusion portions PP. The plurality of second cover layers CL2 are disposed so as to cover side surfaces and top surfaces of the plurality of first cover layers CL1.

For example, the plurality of second cover layers CL2 are formed of the same material as the anode 121 disposed in the active area AA. For example, the plurality of second cover layers CL2 are formed by the same process with the same material as the anode 121 disposed in the active area AA, but is not limited thereto. Therefore, the plurality of first cover layers CL1 and the plurality of second cover layers CL2 are configured to cover the ends of the plurality of protrusion portions PP and protect the ends of the plurality of protrusion portions from an etching solution, after a step of forming the second planarization layer 115b and the anode 121, for example, during the processing process such as dry etching.

In the display apparatus 700 according to still another exemplary embodiment of the present disclosure, the first cover layer CL1 and the second cover layer CL2 which cover ends of the plurality of protrusion portions PP of the power line PL are disposed to further minimize or at least reduce the moisture permeation through the side surfaces of the plurality of protrusion portions PP.

Specifically, in the display apparatus 700 according to still another exemplary embodiment of the present disclosure, the plurality of protrusion portions PP are disposed on the side surface of the power line PL. The plurality of first cover layers CL1 and the plurality of second cover layers CL2 are disposed on the ends of the plurality of protrusion portions PP. The plurality of first cover layers CL1 are formed of the same material as the second planarization layer 115b and the plurality of second cover layers CL2 are formed of the same material as the anode 121. Therefore, the plurality of first cover layers CL1 and the plurality of second cover layers CL2 cover a side surface and a top surface of the power line PL which may be formed with a triple structure of titanium (Ti)/aluminum (Al)/titanium (Ti). Therefore, the ends of the plurality of protrusion portions PP are protected during the process to minimize or at least reduce erosion of the second layer PPb of the protrusion portion PP including aluminum (Al) of the power line PL and minimize or at least reduce a void or seam structure which occurs on the ends of the plurality of protrusion portions PP. Therefore, the void or seam structure is disconnected in at least a part along the side surfaces of the plurality of protrusion portions PP of the power line PL so that the moisture permeation due to the capillary phenomenon which may occur through the void or seam structure formed along the side surfaces of the plurality of protrusion portions PP may be minimized or at least reduced. Accordingly, in the display apparatus 700 according to another exemplary embodiment of the present disclosure, the plurality of first cover layers CL1 and the plurality of second cover layers CL2 which cover ends of the plurality of protrusion portions PP of the power line PL are disposed. Therefore, the moisture permeation through the side surfaces of the plurality of protrusion portions PP is further minimized or at least reduced and the display quality and the reliability of the display apparatus 700 may be further improved.

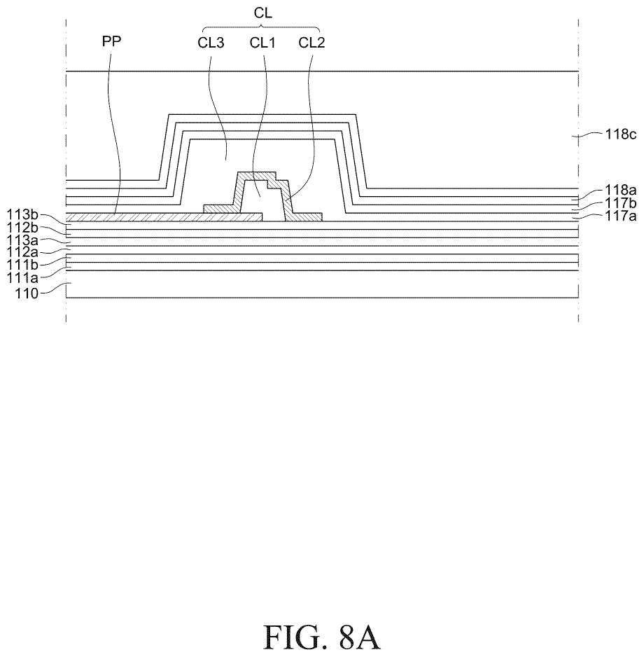

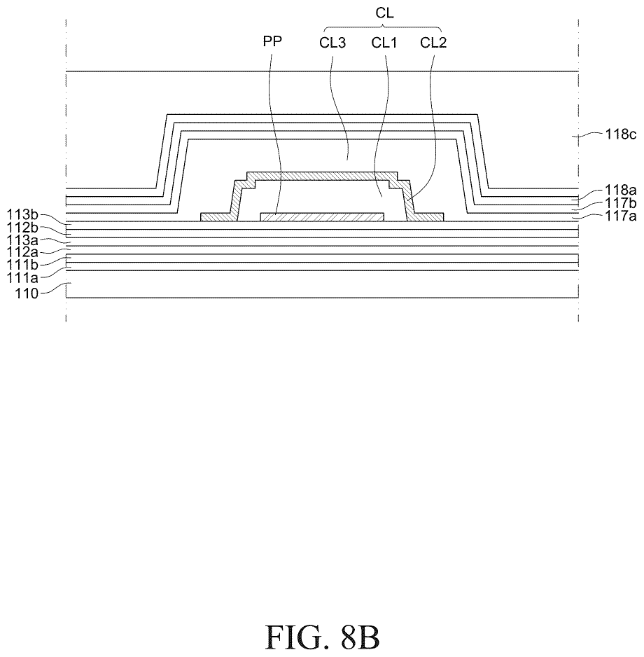

FIGS. 8A and 8B are cross-sectional views of a protrusion portion and a cover unit of a display apparatus according to another exemplary embodiment of the present disclosure. The only difference between a display apparatus 800 of FIGS. 8A and 8B and the display apparatus 700 of FIGS. 7A to 7B is that a third cover layer CL3 is further disposed, so that a redundant description for the substantially same part will be omitted. The same configuration will be denoted with the same reference numeral.

The plurality of cover layers CL includes a plurality of first cover layers CL1, a plurality of second cover layers CL2, and a third cover layer CL3.

Referring to FIGS. 8A and 8B, the plurality of first cover layers CL1 are disposed on ends of the plurality of protrusion portions PP. The plurality of first cover layers CL1 are disposed so as to cover side surfaces and top surfaces of the plurality of protrusion portions PP.

For example, the plurality of first cover layers CL1 are formed of the same material as the second planarization layer 115b disposed in the active area AA. For example, the plurality of first cover layers CL1 are formed by the same process with the same material as the second planarization layer 115b disposed in the active area AA, but is not limited thereto. Therefore, the plurality of cover layers CL are configured to cover and protect ends the plurality of protrusion portions PP in a process after the step of forming the second planarization layer 115b.

The plurality of second cover layers CL2 are disposed on the plurality of first cover layers CL1. For example, the plurality of second cover layers CL2 may be disposed so as to overlap the end of the second parts PP2 of the plurality of protrusion portions PP. The plurality of second cover layers CL2 are disposed so as to cover side surfaces and top surfaces of the plurality of first cover layers CL1.

For example, the plurality of second cover layers CL2 are formed of the same material as the anode 121 disposed in the active area AA. For example, the plurality of second cover layers CL2 are formed by the same process with the same material as the anode 121 disposed in the active area AA, but is not limited thereto.

The plurality of third cover layers CL3 are disposed on the plurality of second cover layers CL2. For example, the plurality of third cover layers CL3 may be disposed so as to overlap the end of the second parts PP2 of the plurality of protrusion portions PP. The plurality of third cover layers CL3 are disposed so as to cover top surfaces, side surfaces, and ends of the plurality of second cover layers CL2.

For example, the plurality of third cover layers CL3 are formed of the same material as the bank 116a disposed in the active area AA. For example, the plurality of second cover layers CL2 are formed by the same process with the same material as the bank 116a disposed in the active area AA, but is not limited thereto.

Therefore, the plurality of first cover layers CL1, the plurality of second cover layers CL2, and the plurality of third cover layers CL3 are configured to cover the ends of the plurality of protrusion portions PP and protect the ends of the plurality of protrusion portions from an etching solution, after a step of forming the second planarization layer 115b, the anode 121, and the bank 116a, for example, during the processing process such as dry etching.

In the display apparatus 800 according to still another exemplary embodiment of the present disclosure, the plurality of first cover layers CL1, the plurality of second cover layers CL2, and the plurality of third cover layers CL3 which cover ends of the plurality of protrusion portions PP of the power line PL are disposed to further minimize the moisture permeation through the side surfaces of the plurality of protrusion portions PP.

Specifically, in the display apparatus 800 according to still another exemplary embodiment of the present disclosure, the plurality of protrusion portions PP are disposed on the side surface of the power line PL. The plurality of first cover layers CL1, the plurality of second cover layers CL2, and the plurality of third cover layers CL3 are disposed on the ends of the plurality of protrusion portions PP. The plurality of first cover layers CL1 are formed of the same material as the second planarization layer 115b, the plurality of second cover layers CL2 are formed of the same material as the anode 121, and the plurality of third cover layers CL3 are formed of the same material as the bank 116a. Therefore, the plurality of first cover layers CL1, the plurality of second cover layers CL2, and the plurality of third cover layers CL3 cover a side surface and a top surface of the power line PL which may be formed with a triple structure of titanium (Ti)/aluminum (Al)/titanium (Ti). Therefore, the ends of the plurality of protrusion portions PP are protected during the process to minimize or at least reduce erosion of the second layer PPa of the protrusion portion PP including aluminum (Al) of the power line PL and minimize or at least reduce a void or seam structure which occurs on the ends of the plurality of protrusion portions PP. Therefore, the void or seam structure is disconnected in at least a part along the side surfaces of the plurality of protrusion portions PP of the power line PL so that the moisture permeation due to the capillary phenomenon which may occur through the void or seam structure formed along the side surfaces of the plurality of protrusion portions PP may be minimized. Accordingly, in the display apparatus 800 according to still another exemplary embodiment of the present disclosure, the plurality of first cover layers CL1, the plurality of second cover layers CL2, and the plurality of third cover layers CL3 which cover ends of the plurality of protrusion portions PP of the power line PL are disposed. Therefore, the moisture permeation through the side surfaces of the plurality of protrusion portions PP is further minimized or at least reduced and the display quality and the reliability of the display apparatus 800 may be further improved.

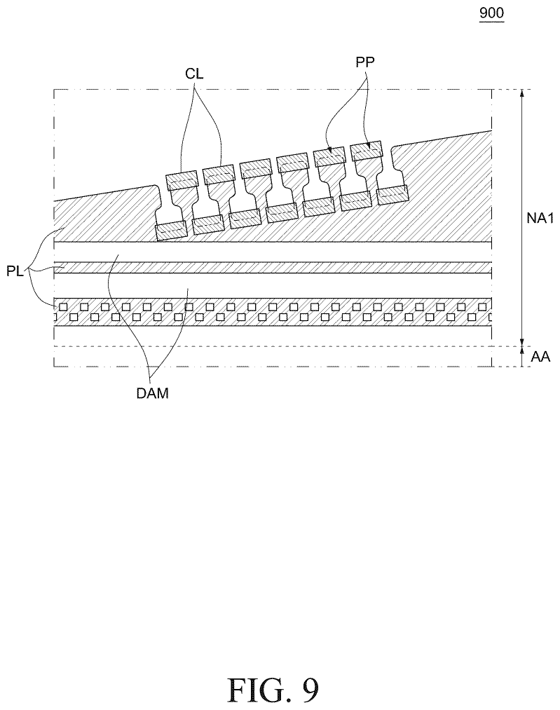

FIG. 9 is an enlarged plan view of a display apparatus according to still another exemplary embodiment of the present disclosure. The only difference between a display apparatus 900 of FIGS. 6A and 6B and the display apparatus 100 of FIGS. 1 to 5D is that a cover layer CL is further disposed between a plurality of protrusion portions PP, so that a redundant description for the substantially same part will be omitted. The same configuration will be denoted with the same reference numeral.

Referring to FIG. 9, the plurality of cover layers CL are further disposed on the side surface of the power line PL between the plurality of protrusion portions PP. The plurality of cover layers CL may also be disposed in a part which overlaps the first parts PP1 of the plurality of protrusion portions PP.

In the display apparatus 900 according to still another exemplary embodiment of the present disclosure, a plurality of cover layers CL which cover the side surface of the power line PL and the ends of the plurality of protrusion portions PP are disposed to further minimize or at least reduce the moisture permeation through the side surfaces of the plurality of protrusion portions PP.

Specifically, in the display apparatus 900 according to still another exemplary embodiment of the present disclosure, the plurality of protrusion portions PP are disposed on the side surface of the power line PL. The plurality of cover layers CL are disposed on the side surface of the power line PL and the ends of the plurality of protrusion portions PP. The plurality of cover layers CL are formed of the same material as the anode 121. Therefore, the plurality of cover layers CL covers a side surface and a top surface of the power line PL which may be formed with a triple structure of titanium (Ti)/aluminum (Al)/titanium (Ti). Therefore, the ends of the plurality of protrusion portions PP are protected during the process to minimize or at least reduce erosion of the second layer PPb of the protrusion portion PP including aluminum (Al) of the power line PL and minimize or at least reduce a void or seam structure which occurs on the ends of the plurality of protrusion portions PP. Therefore, the void or seam structure is disconnected in at least a part along the side surfaces of the plurality of protrusion portions PP of the power line PL so that the moisture permeation due to the capillary phenomenon which may occur through the void or seam structure formed along the side surfaces of the plurality of protrusion portions PP may be minimized. Accordingly, in the display apparatus 900 according to still another exemplary embodiment of the present disclosure, the plurality of cover layers CL which cover the side surface of the power line PL and the ends of the plurality of protrusion portions PP are disposed. Therefore, the moisture permeation through the side surfaces of the plurality of protrusion portions PP may be further minimized or at least reduced and the display quality and the reliability of the display apparatus 900 may be further improved.

The exemplary embodiments of the present disclosure can also be described as follows:

According to an aspect of the present disclosure, a display apparatus includes a substrate including an active area in which a plurality of sub pixels are disposed and a non-active area which encloses the active area, a plurality of light emitting diodes which are disposed in each of the plurality of sub pixels on the substrate and includes an anode, an emission layer, and a cathode, a power line which is disposed on a layer lower than the anode in the non-active area and includes a plurality of protrusion portions protruding from a side surface to the outside, and a plurality of cover layers which are disposed so as to cover ends of the plurality of protrusion portions.

Each of the plurality of protrusion portions may include a first part which extends from a side surface of the power line; and a second part which extends from the first part to the outside and has a width larger than the first part, and the plurality of cover layers is disposed on an end of the second part.

The plurality of cover layers may be further disposed on a side surface of the power line between the plurality of protrusion portions.

The plurality of cover layers may be formed of the same material as the anode.

The display apparatus may further comprise a planarization layer disposed between the substrate and the anode in the active area.

The plurality of cover layers may include a first cover layer which is formed of the same material as the planarization layer.

The plurality of cover layers may further include a second cover layer which is disposed on the first cover layer and is formed of the same material as the anode.

The second cover layer may be disposed so as to cover a side surface and a top surface of the first cover layer.

The display apparatus may further comprise a bank disposed in the active area so as to cover an end of the anode.

The plurality of cover layers may further include a third cover layer which is disposed on the first cover layer and the second cover layer and is formed of the same material as the bank.

The third cover layer may be disposed so as to cover a top surface, a side surface, and an end of the second cover layer.

The power line may include a first layer, a second layer disposed on the first layer, and a third layer which is disposed on the second layer and is formed of the same material as the first layer.

Side surfaces of the first layer, the second layer, and the third layer may be disposed on the same layer on the ends of the plurality of protrusion portions which overlaps the plurality of cover layers.

The display apparatus may further comprise an encapsulation unit disposed on the plurality of light emitting diodes.

On a side surface which does not overlap the plurality of cover layers, among side surfaces of the plurality of protrusion portions, a side surface of the second layer may be located inside more than side surfaces of the first layer and the third layer.

A side surface which does not overlap the plurality of cover layers, among the side surfaces of the plurality of protrusion portions, may be disposed to be in contact with the encapsulation portions.

The first layer and the third layer may include titanium (Ti) and the second layer may include aluminum (Al).

According to another embodiment of the present disclosure, a display apparatus includes a substrate including an active area in which a plurality of sub pixels is disposed and a non-active area which encloses the active area, a plurality of light emitting diodes which are disposed in each of the plurality of sub pixels on the substrate and includes an anode, an emission layer, and a cathode, a power line which is disposed on a layer lower than the anode in the non-active area and includes a plurality of protrusion portions protruding from a side surface to the outside, and a plurality of cover layers which are disposed so as to cover ends of the plurality of protrusion portions. Each of the plurality of protrusion portions includes a first part which extends from a side surface of the power line and a second part which extends from the first part to the outside and has a width larger than the first part and each of the plurality of cover layers is disposed on an end of the second part.

The power line may include a first layer, a second layer disposed on the first layer, and a third layer which is disposed on the second layer and is formed of the same material as the first layer.

Side surfaces of the first layer, the second layer, and the third layer may be disposed on the same layer on the ends of the plurality of protrusion portions which overlaps the plurality of cover layers.

The display apparatus may further comprise an encapsulation unit disposed on the plurality of light emitting diodes.

On a side surface which does not overlap the plurality of cover layers, among side surfaces of the plurality of protrusion portions, a side surface of the second layer may be located inside more than side surfaces of the first layer and the third layer.

A side surface which does not overlap the plurality of cover layers, among the side surfaces of the plurality of protrusion portions may be disposed to be in contact with the encapsulation portions.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus comprising:
a substrate including an active area in which a plurality of sub pixels are disposed and a non-active area which encloses the active area;
a plurality of light emitting diodes which are disposed in each of the plurality of sub pixels on the substrate and includes an anode, an emission layer, and a cathode;
a power line on a layer lower than the anode in the non-active area, the power line including a plurality of protrusion portions protruding from a side surface to an outside; and
a plurality of cover layers that cover ends of the plurality of protrusion portions.

2. The display apparatus according to claim 1, wherein each of the plurality of protrusion portions includes:
a first part which extends from a side surface of the power line; and
a second part which extends from the first part to the outside, the second part having a width that is larger than the first part, and
wherein the plurality of cover layers are on an end of the second part.

3. The display apparatus according to claim 2, wherein the plurality of cover layers are on a side surface of the power line between the plurality of protrusion portions.

4. The display apparatus according to claim 1, wherein the plurality of cover layers include a same material as the anode.

5. The display apparatus according to claim 1, further comprising:
a planarization layer between the substrate and the anode in the active area,
wherein the plurality of cover layers include a first cover layer that includes a same material as the planarization layer.

6. The display apparatus according to claim 5, wherein the plurality of cover layers further include a second cover layer on the first cover layer and includes a same material as the anode.

7. The display apparatus according to claim 6, wherein the second cover layer covers a side surface and a top surface of the first cover layer.

8. The display apparatus according to claim 6, further comprising:
a bank in the active area, the bank covering an end of the anode,
wherein the plurality of cover layers further include a third cover layer that is on the first cover layer and the second cover layer and includes a same material as the bank.

9. The display apparatus according to claim 8, wherein the third cover layer covers a top surface, a side surface, and an end of the second cover layer.

10. The display apparatus according to claim 1, wherein the power line includes a first layer, a second layer on the first layer, and a third layer on the second layer and includes a same material as the first layer, and
side surfaces of the first layer, the second layer, and the third layer are on a same layer on the ends of the plurality of protrusion portions which overlap the plurality of cover layers.

11. The display apparatus according to claim 10, further comprising:
an encapsulation unit on the plurality of light emitting diodes,
wherein on a side surface that is non-overlapping with the plurality of cover layers, among side surfaces of the plurality of protrusion portions, a side surface of the second layer is located inside more than side surfaces of the first layer and the third layer.

12. The display apparatus according to claim 11, wherein a side surface that is non-overlapping with the plurality of cover layers, among the side surfaces of the plurality of protrusion portions, is in contact with the encapsulation unit.

13. The display apparatus according to claim 10, wherein the first layer and the third layer include titanium and the second layer includes aluminum.

14. A display apparatus comprising:
a substrate including an active area in which a plurality of sub pixels are disposed and a non-active area which encloses the active area;
a plurality of light emitting diodes in each of the plurality of sub pixels on the substrate and includes an anode, an emission layer, and a cathode;
a power line on a layer lower than the anode in the non-active area, the power line including a plurality of protrusion portions protruding from a side surface to an outside; and
a plurality of cover layers that cover ends of the plurality of protrusion portions,
wherein each of the plurality of sub pixels includes:
a first part that extends from a side surface of the power line; and
a second part that extends from the first part to the outside, the second part having a width that is larger than the first part,
wherein the plurality of cover layers are on an end of the second part.

15. The display apparatus according to claim 14, wherein the power line includes a first layer, a second layer on the first layer, and a third layer on the second layer and includes a same material as the first layer, and
side surfaces of the first layer, the second layer, and the third layer are on a same layer on the ends of the plurality of protrusion portions which overlap the plurality of cover layers.

16. The display apparatus according to claim 15, further comprising:
an encapsulation unit on the plurality of light emitting diodes,
wherein on a side surface that is non-overlapping with the plurality of cover layers, among side surfaces of the plurality of protrusion portions, a side surface of the second layer is located inside more than side surfaces of the first layer and the third layer.

17. The display apparatus according to claim 16, wherein a side surface that is non-overlapping with the plurality of cover layers, among the side surfaces of the plurality of protrusion portions is in contact with the encapsulation unit.
